(19) United States
(12) Patent Application Publication
(10) Pub. No.: US 2004/0224469 A1
(43) Pub. Date: Nov. 11, 2004

(54) Method for forming a strained semiconductor substrate

(75) Inventors: Chong Wee Lim, Urbana, IL (US); Yong-Lim Foo, Urbana, IL (US); Sukwon Hong, Urbana, IL (US); Kenneth A. Bratland, Mahomet, IL (US); Timothy Spila, Savoy, IL (US); Benjamin Cho, Morris, IL (US); Kenji Ohmori, Urbana, IL (US); Joseph Greene, Champaign, IL (US)

Correspondence Address: GREER, BURNS & CRAIN, LTD., 25th Floor, 300 South Wacker Drive, Chicago, IL, 60606, US

(73) Assignee: The Board of Trustees of the University of Illinois

(21) Appl. No.: 10/434,402

(22) Filed: May 8, 2003

(51) Int. Cl. H01L 21/336

(52) U.S. Cl. 438/285; 438/296

(57) ABSTRACT

A method of manufacturing a strained semiconductor substrate includes the steps of provide a Si substrate and depositing a strained Si₁₋ₓGeₓ layer on the Si substrate. The Si substrate and strained Si₁₋ₓGeₓ layer are subjected to rapid thermal annealing which forms a relaxed Si₁₋ₓGeₓ layer on the Si substrate. The method further includes the steps of depositing a buffer Si₁₋ₓGeₓ layer on the relaxed Si₁₋ₓGeₓ layer, and depositing Si on the buffer Si₁₋ₓGeₓ layer. The buffer Si₁₋ₓGeₓ layer causes the deposited Si to form a strained Si layer on the buffer Si₁₋ₓGeₓ layer with the combined layers forming the strained semiconductor substrate.

### STATEMENT OF GOVERNMENT INTEREST

This invention was made with United States government assistance through the U.S. Department of Energy Grant No. DEFG02-91ER45439. The government has certain rights in this invention.

### FIELD OF THE INVENTION

The field of the invention is semiconductor fabrication. A particular field of the invention is sub-micron semiconductor fabrication.

### BACKGROUND OF THE INVENTION

Microprocessor chips, which serve as the brains of computers and electronic devices, are based on advanced processes and materials that enable the manufacturing of high-speed transistors to be formed on silicon (Si) substrates. Generally, atomically-flat, relaxed (e.g., Si₁₋ₓGeₓ) thin film layers on Si substrates can be used as building blocks for deep sub-micron and ultra-high speed next-generation transistors that are based on strained-Si technology, which increases transistor speed. Relaxed Si₁₋ₓGeₓ thin film layers may also be used as templates for the deposition of epitaxial nitrides, suicides, ferroelectrics and other classes of materials by adjusting the template lattice constant (i.e., varying the Ge concentration in the Si₁₋ₓGeₓ thin film layer).

A method of forming a relaxed Si₁₋ₓGeₓ layer on a Si substrate utilizes a grading technique. A disadvantage of this technique, however, is that compositionally graded layers have an inherent built-in strain that causes a rough surface as the Si₁₋ₓGeₓ layer is relaxed. As a result, the grading technique method can potentially limit the size of next-generation transistors, and prevent further miniaturization of integrated circuits.

In order to circumvent the roughness problem, typically, formation of a flat relaxed Si₁₋ₓGeₓ layer formed on a Si substrate is achieved by a chemical mechanical polishing of a deposited rough, thick relaxed Si₁₋ₓGeₓ layer to remove its surface roughness. Thereafter, it is known to again perform a chemical mechanical polishing of a strained semiconductor substrate during the process of forming shallow trench isolations to smooth the strained semiconductor substrate.

While the use of the chemical mechanical polishing process can produce a Si₁₋ₓGeₓ layer having a substantially flat surface, it is an inherently expensive process. It is therefore an ongoing goal to reduce the number of times that chemical mechanical polishing is required in order to form an integrated circuit on a Si₁₋ₓGeₓ layer formed on a Si substrate. Another drawback of the chemical mechanical polishing process is that is an inherently “dirty” process capable of causing contamination of the Si substrate and any other epitaxial layers on the substrate, especially prior to the formation of shallow trench isolations since slurries and abrasives are used for lapping and polishing of the Si₁₋ₓGeₓ layer. Contamination is particularly undesirable prior to the formation of shallow trench isolations.

### SUMMARY OF THE INVENTION

A method of manufacturing a strained semiconductor substrate includes steps of providing a Si substrate, depositing a strained Si₁₋ₓGeₓ layer on the Si substrate, and rapid thermal annealing the strained Si₁₋ₓGeₓ layer to form a relaxed Si₁₋ₓGeₓ layer on the Si substrate. The method further includes a step of depositing a buffer Si₁₋ₓGeₓ layer on the relaxed Si₁₋ₓGeₓ layer. Additionally, a step of depositing Si on the buffer Si₁₋ₓGeₓ layer enables the deposited Si to form a strained Si layer on the buffer Si₁₋ₓGeₓ layer and form the strained semiconductor substrate. The method may employ various deposition processes to deposit the strained Si₁₋ₓGeₓ layer and the Si on the Si substrate, and to provide a strained semiconductor substrate that may have integrated circuits formed thereon.

### BRIEF DESCRIPTION OF THE DRAWINGS

FIG. 1 shows a flow chart of the preferred functionality of a method of manufacturing a strained semiconductor substrate;

FIGS. 2A-2L show a cross-sectional schematic useful in illustrating the steps of FIG. 1 prior to the step of forming the integrated circuit; and

FIGS. 3A-3M show an alternate cross-sectional schematic useful in illustrating the steps of FIG. 1 prior to the step of forming the integrated circuit.

### DETAILED DESCRIPTION OF THE PREFERRED EMBODIMENTS

The invention concerns methods for manufacturing a strained semiconductor substrate, such as a silicon (Si) and germanium (Ge) wafer, that are used to build integrated circuits having enhanced device characteristics. In preferred embodiments, a strained Si₁₋ₓGeₓ layer provided with a first lattice constant is formed over a Si substrate having a second lattice constant, which is different from the first lattice constant. This difference in lattice constant creates a strained semiconductor layer. The strained Si₁₋ₓGeₓ layer is then rapid thermal annealed to form a relaxed Si₁₋ₓGeₓ layer on the Si substrate. One advantage of the present methods are that the relaxed Si₁₋ₓGeₓ layer does not require chemical mechanical polishing prior to a depositing of Si on the relaxed Si₁₋ₓGeₓ layer (i.e., prior to the formation of shallow trench isolations in the strained semiconductor substrate). This decreases the number of times that chemical mechanical polishing is required to form an integrated circuit, and ensures that contamination does not occur due to chemical mechanical polishing of the strained semiconductor substrate prior to the formation of shallow trench isolations. Moreover, the step of depositing Si on the relaxed Si₁₋ₓGeₓ layer according to the present methods can occur either prior to or after formation of shallow trench isolations.

The provided methods may form, for example, Si₁₋ₓGeₓ template layers on Si substrates which can then be used as building blocks in deep sub-micron and ultra-high speed transistors based on strained-Si technology. An advantage of using strained-Si technology versus unstrained-Si technology is that strained-Si technology is known to improve performance and decrease power consumption in semiconductors. In addition to forming template layers on Si substrates, the methods may also be used in template engineering for depositing nitrides, silicides, ferroelectrics, and other classes of materials by adjusting a template lattice constant (e.g., varying the Ge concentration in the Si₁₋ₓGeₓ material). The present methods are further advantageous in that conventional grading techniques, which can limit transistor size, are not required for forming the strained Si substrate.

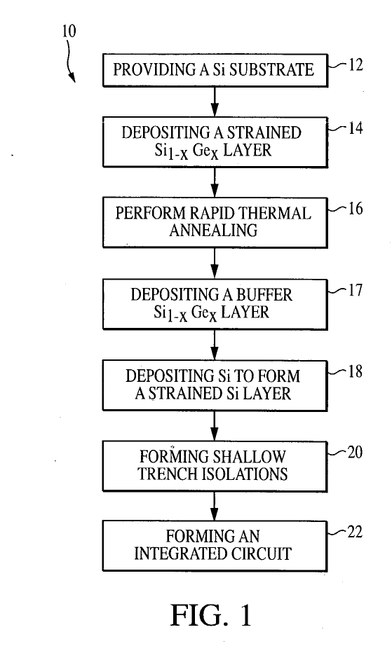

Turning now to the drawings, FIG. 1 is a flowchart illustrating steps of a preferred method 10 of manufacturing a strained semiconductor substrate which has an integrated circuit formed thereon. The preferred embodiment method 10 begins with a step of providing a Si substrate 12. Next, a strained Si₁₋ₓGeₓ layer 14 is deposited on the Si substrate 12 and rapid thermal annealed 16 to form a relaxed, generally flat (i.e., atomically-flat) Si₁₋ₓGeₓ layer on the Si substrate. A buffer Si₁₋ₓGeₓ layer 17 is deposited or grown on the Si₁₋ₓGeₓ layer 14 to further reduce roughness. Preferably, the Si₁₋ₓGeₓ layer 14 is a Si_{0.7}Ge_{0.3} layer that is formed by chemical vapor deposition at a temperature of less than 450° C. Moreover, it is desirable that the chemical vapor deposition occurs in the presence of a surfactant, such as hydrogen, and that the formed Si₁₋ₓGeₓ layer 14 has a thickness of 120 nm or greater when x=0.3. Preferably, the thickness of the Si₁₋ₓGeₓ layer 14 ranges between 120 nm to 300 nm and x varies between 0.3 and 0.5. That is, it is contemplated that the percentage composition of Si and Ge in the strained Si₁₋ₓGeₓ layer 14 may vary

Generally, there are two modes of strained relaxation for Si₁₋ₓGeₓ on Si. One mode comprises of strain roughening which occurs through massive adatom motion as a consequence of spatial gradients in the surface chemical potential. The other mode is due to misfit dislocation which occurs by forming misfit segments that run parallel to the <110> direction in the Si₁₋ₓGeₓ/Si interface and are terminated with threading arms running up to surfaces or interfaces.

For typical furnace-type annealing processes that occur over extended periods of time (e.g., hours), strain roughening is the preferred mode of strain relaxation since the activation energy for strain roughening is less than the activation energy for misfit dislocation. However, an advantage of the present invention is that it can be used to induce strained relaxation in the strained Si₁₋ₓGeₓ layer without appreciable surface roughening of the strained Si₁₋ₓGeₓ layer. That is, the rapid thermal annealing process enables enhancement of the misfit dislocation formation which has high activation energy, while suppressing the strain roughening which has low activation energy.

Furthermore, unlike furnace-type annealing or the like which gradually raises the temperature of substrates deposited therein, rapid thermal annealing in the present invention refers to processes that increase the temperature of substrates rapidly and for short time durations (e.g., 30 seconds). Although the processing time for rapid thermal annealing is very short relative to furnace-type annealing processes, the exact processing time may vary depending on the specific equipment used to perform the rapid thermal annealing. In one embodiment, a strained semiconductor substrate was formed by a rapid thermal anneal of a strained Si₁₋ₓGeₓ layer after it was deposited on a Si substrate for 30 seconds at a temperature of 1000° C., which induced relaxation of the strained Si₁₋ₓGeₓ layer. Preferred time and temperature ranges for the rapid thermal anneal process are from 10 to 1000 seconds and from 850 to 1100° C.

Rapid thermal annealing may be performed in a variety of ways, including direct resistive heating, laser annealing, IR lamp heating, RF heating, etc., or a combination thereof. One advantage of rapid thermal annealing is that it selectively induces relaxation of the strained Si₁₋ₓGeₓ layer by a process of misfit dislocation formation, rather than the process of surface roughening which occurs during furnace-type annealing processes. Selectively inducing relaxation of the strained Si₁₋ₓGeₓ layer by a misfit dislocation process enables the relaxed Si₁₋ₓGeₓ layer to be atomically flatter than a strained Si₁₋ₓGeₓ layer relaxed using furnace-type annealing processes. More specifically, rapid thermal annealing makes the rate of formation of misfit dislocation much faster than the rate of surface roughening. As previously discussed, the buffer Si₁₋ₓGeₓ layer is deposited on the relaxed Si₁₋ₓGeₓ layer to further smooth the substrate's surface defined by the relaxed Si₁₋ₓGeₓ layer and to reduce the threading dislocation density of the relaxed Si₁₋ₓGeₓ layer.

After the strained Si₁₋ₓGeₓ layer 14 is relaxed, the method of manufacturing a strained semiconductor substrate continues with a step of depositing the buffer Si₁₋ₓGeₓ layer 17 on the relaxed Si₁₋ₓGeₓ layer, and then a step of depositing Si on the relaxed Si₁₋ₓGeₓ layer 18 which causes the Si to form a strained Si layer on the buffer Si₁₋ₓGeₓ layer. As one skilled in the art will recognize, the process implementing the deposition of the Si and the Si₁₋ₓGeₓ layers can be varied. For example, the Si₁₋ₓGeₓ layers may be deposited on a Si substrate by any thin film deposition technique. Preferably, the steps of depositing the strained Si₁₋ₓGeₓ layer and the Si are performed using an ultra-high vacuum chemical vapor deposition process that is amenable to the incorporation of the steps of the invention into electrical circuits and integrated circuit device applications. Those skilled in the art will recognize other appropriate deposition processes, such as solid-source deposition (e-beam evaporators, sublimation sources, Knudsen cell), ion-beam assisted deposition, and gas-source epitaxy (ALE, CVD, AP-CVD, PE-CVD, RT-CVD, UHV-CVD, LP-CVD, MO-CVD, CB-CVD, GS-MBE, etc.) using chemical precursors, that are available for depositing the Si₁₋ₓGeₓ layers and the Si to form the strained semiconductor substrate.

Once the strained semiconductor substrate is formed, other processing steps to form an integrated circuit on the strained silicon substrate can be performed. By way of example, shallow trench isolations can be formed 20 in the relaxed Si₁₋ₓGeₓ layer and the strained Si layer to enable patterning of semiconductor devices on the strained semiconductor substrate. Then, an integrated circuit may then be formed 22 on the strained semiconductor substrate using known microelectronic fabrication techniques. It will be understood that there are many additional and alternative steps to those discussed with reference to the preferred method 10 that may be practiced in other method embodiments. By way of example, the step of depositing Si 18 may occur after the formation of the shallow trench isolations in step 20.

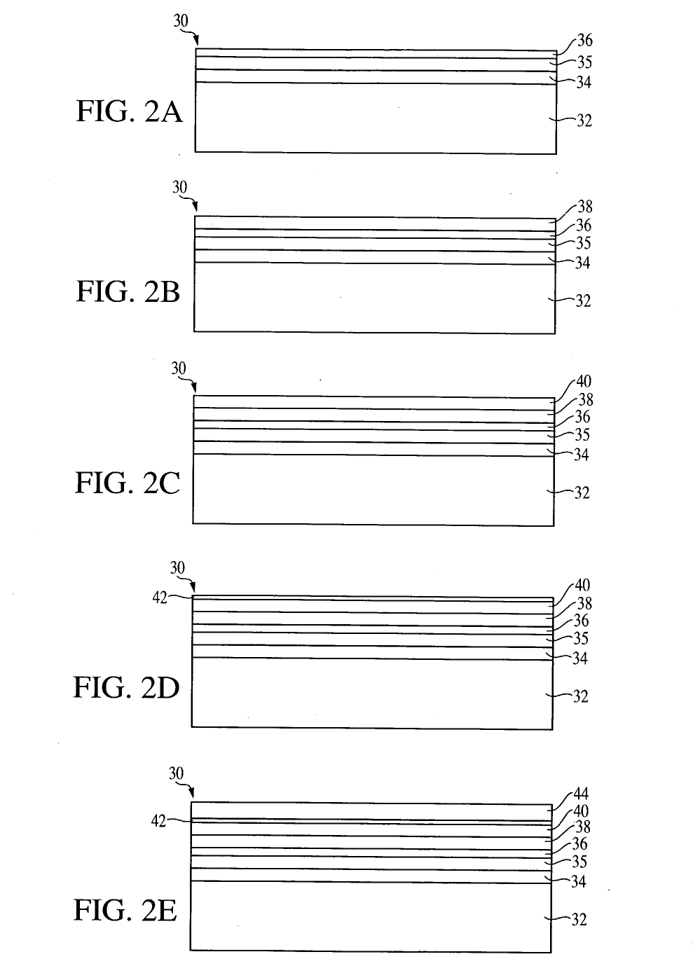

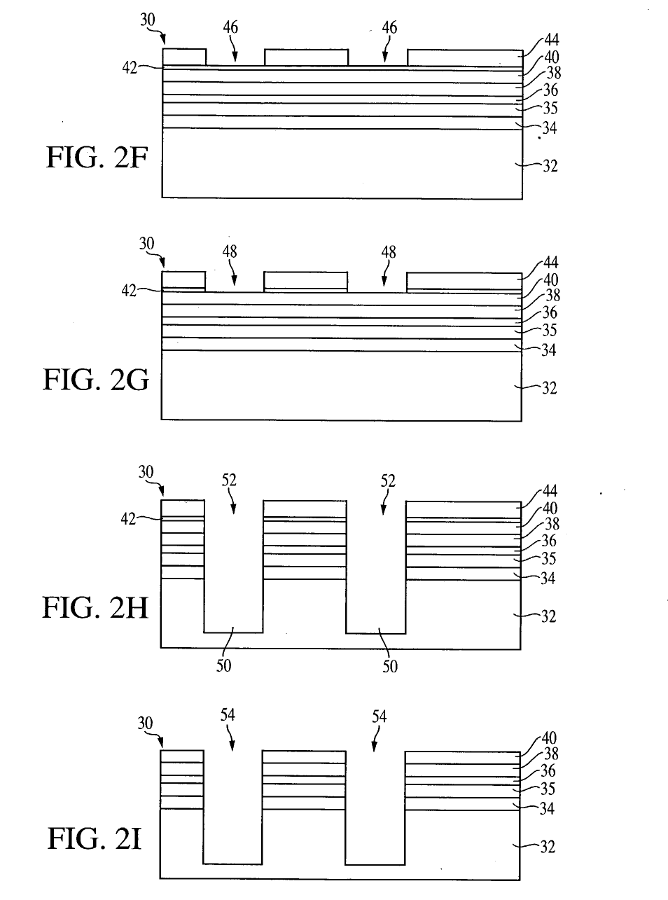

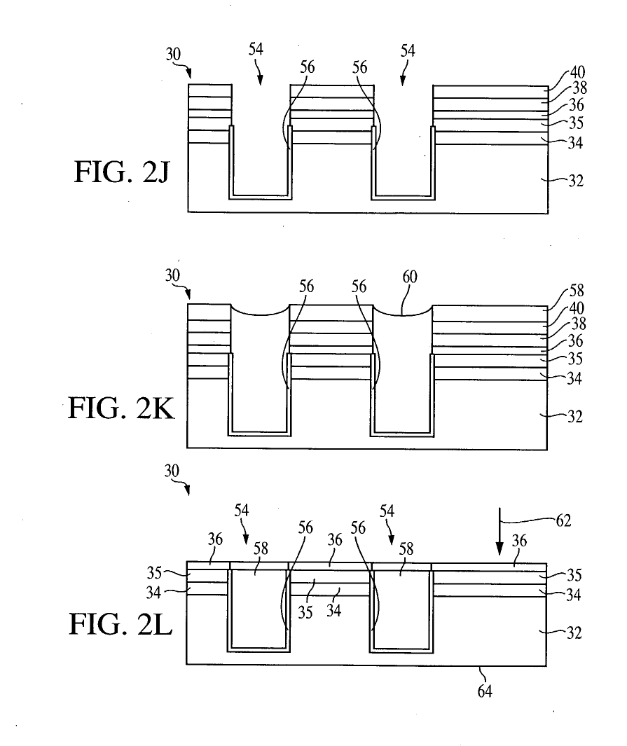

Referring now to FIGS. 2A-L, a cross-sectional schematic 30 is illustrated for preparing a strained semiconductor substrate prior to formation of an integrated circuit thereon (i.e., prior to step 22 of the method of FIG. 1). Initially, as shown in FIG. 2A a Si substrate 32 has a relaxed Si₁₋ₓGeₓ layer 34 and a buffer Si₁₋ₓGeₓ layer 35 thereon, and a strained Si layer 36 on the buffer Si₁₋ₓGeₓ layer 35 according to the deposition and rapid thermal annealing steps described above, which reduces the number of times that chemical mechanical polishing is required to form an integrated circuit. Furthermore, chemical mechanical polishing of the strained Si layer 36 is not required prior to the formation of shallow trench isolations in the Si substrate 32. Preferably, the strained Si layer 36 has a thickness of the order of 150 nm. Moreover, it is desirable that rapid thermal annealing is used to relax the strained Si layer 36 so that it has a generally flat surface upon completion of the deposition process, with the buffer Si₁₋ₓGeₓ layer 35 further smoothing the surface of the Si substrate 32. A spin on glass layer 38 is then formed on the strained Si layer 36 (FIG. 2B), and a nitride layer 40 is formed on the spin on glass layer 38 (FIG. 2C). The spin on glass layer 38 acts as an intermediate layer to the nitride layer 40 to reduce defects due to stress. Next, as illustrated in FIG. 2D an anti-reflective coating layer 42 is formed on the nitride layer 40, and then a photoresist layer 44 is formed on the anti-reflective coating layer 42 (FIG. 2E). The anti-reflective coating layer 42 is used to reduce standing wave formation in the photoresist layer 44 during photolithography, which improves the resolution in pattern line width. The photoresist layer 44 can be patterned using known lithography methods to isolate regions of the Si substrate 32.

The photoresist layer 44 illustrated in FIG. 2E is etched using known integrated circuit techniques to begin formation of shallow trench isolations, shown generally by arrows 46 (FIG. 2F). Then, the anti-reflective coating 42 is removed which continues formation of the shallow trench isolations as shown by arrows 48 (FIG. 2G). In a similar manner, FIG. 2H illustrates the removal of the nitride layer 40, the spin on glass layer 38, the strained Si layer 36, the relaxed Si₁₋ₓGeₓ layer 34, and portions of the Si substrate 32 to form Si substrate boundaries 50. Arrows 52 illustrate further formation of the shallow trench isolations.

Next, the photoresist layer 44 is removed (FIG. 21) to form shallow trench isolations, generally indicated by arrows 54. Next, a liner oxide layer 56 is formed on the deposited Si layer 36, the buffer Si₁₋ₓGeₓ layer 35, the relaxed Si₁₋ₓGeₓ layer 34, and the Si substrate boundaries 50 of the Si substrate 32 (FIG. 2J). The liner oxide layer 56 is used to improve the isolation properties of the shallow trench isolations 54. The shallow trench isolations 54 are then filled with an oxide 58 using, for example, a high density plasma chemical vapor deposition process that also fills the shallow trench isolations 54 (FIG. 2K). Usually, the insulation quality of the oxide 58 that fills the shallow trench isolations 54 is less than the oxide used for the liner oxide layer 56.

After the filling process, the strained Si layer 36 is not chemically mechanically polished. Rather, the filling process causes the oxide 58 to be formed with a rough surface 60. The rough surface 60 is then chemically mechanically polished in the direction of an arrow 62 to remove the rough surface of the oxide 58, the nitride layer 40, and the spin on glass layer 38 (FIG. 2L). Upon completion of the chemical mechanical polishing, a strained semiconductor substrate 64 having shallow trench isolations 54 filled with the oxide 58 and an atomically-flat strained Si layer 36 is formed. Thereafter, integrated circuits may be formed on the strained semiconductor substrate 64. As those skilled in the art will recognize, the processes described in FIGS. 2A-2L can be implemented using known microelectronic fabrication techniques.

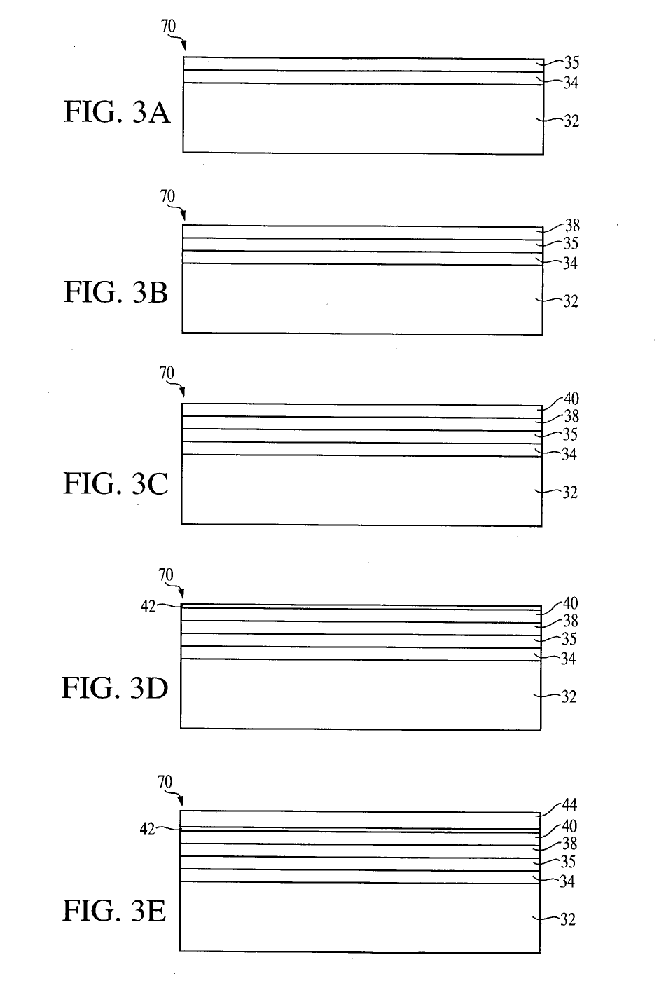

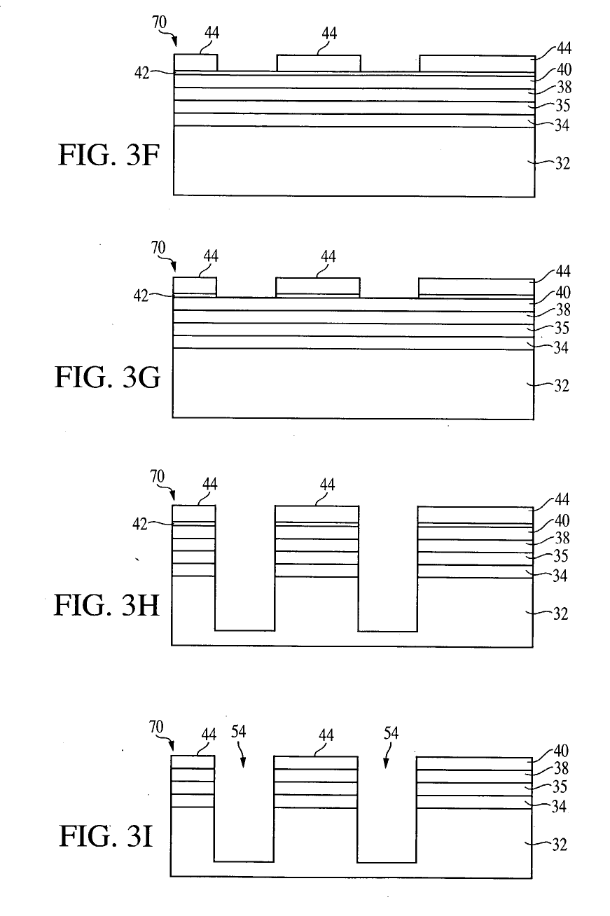

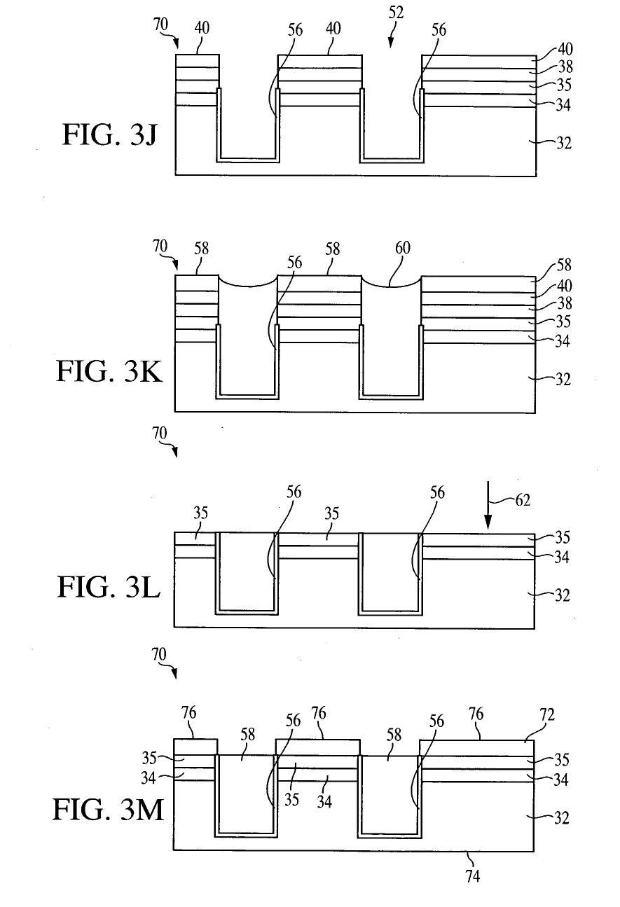

Turning now to FIGS. 3A-M, another exemplary cross-sectional schematic 70 is illustrated for preparing a strained semiconductor substrate prior to formation of an integrated circuit thereon. FIG. 3 uses reference numerals from FIG. 2 to identify like parts. Unlike the method shown in FIG. 2A which includes the deposited Si layer 36 on the buffer Si₁ ,Ge, layer 35, the present method as illustrated in FIG. 3A has only the relaxed Si₁₋ₓGeₓ layer 34 and buffer Si₁₋ₓGeₓ layer 35 formed on the Si substrate 32 prior to further shallow trench isolation processing steps. In this embodiment, the shallow trench isolation process is used to make the relaxed Si₁₋ₓGeₓ layer 34 more planar before the strained Si deposition. An advantage of this method is that the strained Si can be formed at the location of integrated circuit fabrication rather than the location of the wafer manufacturer. The relaxed Si₁₋ₓGeₓ layer 34 and the buffer Si₁₋ₓGeₓ layer 35 provided on the Si substrate 32 are formed according to the method steps 12-16 of FIG. 1. As in the previous embodiment illustrated in FIGS. 2A-2L, the present embodiment has the advantage of reducing the number of times chemical mechanical polishing is required to form an integrated circuit, and eliminates chemical mechanical polishing of the Si substrate 32 prior to the formation of shallow trench isolations. FIGS. 3B-3L depict similar processing steps as FIGS. 2B-2L except that the deposited Si layer 36 of FIG. 2A is absent.

Upon completion of the chemical mechanical polishing illustrated in FIG. 3L, Si 72 is deposited, for example, by chemical vapor deposition on the buffer Si₁₋ₓGeₓ layer 35 to form a strained semiconductor substrate 74. Similar to the chemical mechanical polishing of the strained semiconductor substrate 64 of FIG. 2L wherein chemical mechanical polishing occurs up to the strained Si layer 36, but does not include polishing of the deposited Si which forms a strained Si layer that is partitioned into separated parts 76 (FIG. 3M) upon completion of the chemical mechanical polishing. That is, the separated parts 76 are formed on the buffer Si₁₋ₓGeₓ layer 35, which is partitioned by the oxide 58 that fills the shallow trench isolations 54. Thereafter, the strained semiconductor substrate 74 can then be subjected to further integrated circuit processing steps to form an integrated circuit. Similar to the process steps illustrated in FIG. 2, the process step of FIG. 3 can be implemented using known microelectronic fabrication techniques.

From the foregoing description, it should be understood that improved methods for forming a relaxed semiconductor layer on a Si substrate have been shown and described, which have many desirable attributes and advantages. The present methods enable the formation of template layers, such as a high quality Si₁₋ₓGeₓ/Si interface, which have a smooth surface without requiring a step of chemical mechanical polishing prior to the formation of shallow trench isolations, which reduces the number of times that chemical mechanical polishing is required to form an integrated circuit. Moreover, the methods are fully compatible with standard microelectronic processing techniques without requiring any additional processing steps.

While a specific embodiment of the present invention has been shown and described, it should be understood that other modifications, substitutions and alternatives are apparent to one of ordinary skill in the art. Such modifications, substitutions and alternatives can be made without departing from the spirit and scope of the invention, which should be determined from the appended claims.

Various features of the invention are set forth in the appended claims.

1. A method of manufacturing a strained semiconductor substrate comprising the steps of:
providing a Si substrate;
depositing a strained Si₁₋ₓGeₓ layer on said Si substrate;
rapid thermal annealing said strained Si₁₋ₓGeₓ layer to form a relaxed Si₁₋ₓGeₓ layer on said Si substrate;
depositing a buffer Si₁₋ₓGeₓ layer on said relaxed Si₁₋ₓGeₓ layer; and
depositing Si on said buffer Si₁₋ₓGeₓ layer, said buffer Si₁₋ₓGeₓ layer causing said Si to form a strained Si layer on said buffer Si₁₋ₓGeₓ layer.

2. The method of claim 1, further composing the-step of forming shallow trench isolations in said buffer Si₁₋ₓGeₓ layer, said relaxed Si₁₋ₓGeₓ layer, said strained Si layer, and said Si substrate.

3. The method of claim 2, wherein the strained semiconductor substrate is formed without a chemical mechanical polishing of the strained semiconductor substrate prior to formation of said shallow trench isolations.

4. The method of claim 3, further comprising the step of filling said shallow trench isolations prior to a chemical mechanical polishing of said strained semiconductor substrate.

5. The method of claim 1, wherein said step of depositing Si comprises chemical vapor deposition of Si.

6. The method of claim 1, wherein said strained Si₁₋ₓGeₓ layer is a Si_{0.7}Ge_{0.3} layer.

7. The method of claim 1, wherein said step of depositing said strained Si₁₋ₓGeₓ layer comprises chemical vapor deposition of said strained Si₁₋ₓGeₓ layer on said Si substrate in the presence of a surfactant.

8. The method of claim 7, wherein said surfactant is hydrogen.

9. The method of claim 8, wherein said chemical vapor deposition occurs at a temperature less than 450° C.

10. The method of claim 1, wherein said strained Si₁₋ₓGeₓ layer has a thickness greater than 120 nm.

11. The method of claim 1, wherein said rapid thermal annealing is performed by at least one of direct resistive heating, laser annealing, IR lamp heating and RF heating.

12. A method of manufacturing a strained semiconductor substrate comprising the steps of:
providing a Si substrate;
depositing a strained Si₁₋ₓGeₓ layer on said Si substrate;
rapid thermal annealing said strained Si₁₋ₓGeₓ layer to form a relaxed Si₁₋ₓGeₓ layer on said Si substrate without a chemical mechanical polishing of said relaxed Si₁₋ₓGeₓ layer;
depositing a buffer Si₁₋ₓGeₓ layer on said relaxed Si₁₋ₓGeₓ layer; and
depositing Si on said buffer Si₁₋ₓGeₓ layer, said deposited Si forming a strained Si layer on said buffer Si₁₋ₓGeₓ layer.

13. The method of claim 12 further comprising the step of forming shallow trench isolations in said buffer Si₁₋ₓGeₓ layer, said relaxed Si₁₋ₓGeₓ layer, said strained Si layer, and said Si substrate.

14. The method of claim 13 further comprising the step of filling said shallow trench isolations with an oxide.

15. The method of claim 13 further comprising the steps of depositing a spin on glass on said strained Si layer and a nitride on said spin on glass layer.

16. The method of claim 15 further comprising the steps of depositing an anti-reflective coating on said nitride and a photoresist on said anti-reflective coating.

17. The method of claim 12 wherein said strained Si₁₋ₓGeₓ layer is a Si_{0.7}Ge_{0.3} layer.

18. The method of claim 12 wherein said step of depositing said strained Si₁₋ₓGeₓ layer on said Si substrate comprises forming in a chemical deposition process said strained Si₁₋ₓGeₓ layer on said Si substrate in the presence of a surfactant.

19. The method of claim 18 wherein said surfactant is hydrogen.

20. The method of claim 19 wherein said chemical vapor deposition process occurs at a temperature less than 450° C.

21. The method of claim 20 wherein said strained Si₁₋ₓGeₓ layer has a thickness greater than 120 nm.

22. The method of claim 1, wherein the strained Si₁₋ₓGeₓ layer has a first lattice constant while being deposited on the Si substrate having a second lattice constant during formation of said strained semiconductor substrate.

23. The method of claim 12, wherein the strained Si₁₋ₓGeₓ layer has a first lattice constant while being deposited on the Si substrate having a second lattice constant during formation of said strained semiconductor substrate.
